(19) United States
(12) Patent Application Publication
(10) Pub. No.: US 2026/0123429 A1
(43) Pub. Date: Apr. 30, 2026

(54) SEMICONDUCTOR DEVICE

(71) Applicants: TOWER PARTNERS SEMICONDUCTOR CO., LTD., Uozu City (JP); TOWER SEMICONDUCTOR LTD., Haemek (IL)

(72) Inventors: Hiroshige HIRANO, Nara (JP); Yutaka ITO, Hyogo (JP); Hiroaki KURIYAMA, Toyama (JP)

(73) Assignees: TOWER PARTNERS SEMICONDUCTOR CO., LTD., Uozu City (JP); TOWER SEMICONDUCTOR LTD., Haemek (IL)

(21) Appl. No.: 19/043,590

(22) Filed: Feb. 3, 2025

(30) Foreign Application Priority Data
Oct. 31, 2024 (JP) 2024192167

(51) Int. Cl. H01L 23/58; H10D 86/00

(52) U.S. Cl. CPC H10W 42/00; H10D 86/201

(57) ABSTRACT

A semiconductor device includes a semiconductor substrate, an interlayer insulating film and an element region formed on the semiconductor substrate, and first and second seal rings surrounding the element region. Each of the first and second seal rings is formed of a layered conductive film including at least one linear interconnect layer and at least one linear via layer, and are insulated from each other or electrically connected only in an uppermost one of layers forming the conductive film. The first seal ring is electrically insulated from the semiconductor substrate. The second seal ring is electrically connected to the semiconductor substrate.

### CROSS-REFERENCE TO RELATED APPLICATION

This application claims priority to Japanese Patent Application No. 2024-192167 filed on Oct. 31, 2024, the entire disclosure of which is incorporated by reference herein.

### BACKGROUND

There are known semiconductor devices having an annular seal ring structure surrounding the outer periphery of logic and analog sections to ensure reliability such as resistance to moisture. In particular, for a semiconductor device using a low dielectric constant insulating film such as a Low-k film in its interconnect structure, it is important to form a stable seal ring structure for reliable moisture resistance in the device. The seal ring structure is sometimes provided to release charges accumulated in the semiconductor device during the manufacture of the device to a substrate.

The seal ring structure is made of, for example, metal interconnects and/or metal vias of Cu (copper) or any other suitable material formed as a continuous line in an annular shape.

For example, Japanese Unexamined Patent Publication No. 2006-147668 (Patent Document 1) is known as a document that discloses the seal ring structure.

### SUMMARY

When Cu is used to form the seal ring structure, Cu is embedded in a groove or a hole formed in an insulating layer. However, Cu is not appropriately embedded or is removed again after embedding in some cases, and the seal ring in a required shape cannot be obtained. If the obtained seal ring has a discontinuous portion (e.g., a hole), moisture resistance is impaired.

Further, the accumulation of the charges during the manufacture of the semiconductor device can damage the device being manufactured.

A semiconductor device having a seal ring structure capable of reducing damage caused by the charge accumulation during the manufacture and ensuring the moisture resistance will be described below.

Studies by the present inventors have found that a seal ring configured to release the charges accumulated during the manufacture of the semiconductor device to a semiconductor substrate is prone to have defects during formation. On the other hand, a seal ring that is not configured to release the charges to the semiconductor substrate is prone to break due to the charge accumulation.

If two or more seal rings are provided, the seal rings are generally connected to the semiconductor substrate in the same manner and are electrically connected to each other for reduction of the charge accumulation in each seal ring or less defects during formation. In contrast, the semiconductor device of the present disclosure includes electrically connected seal rings and insulated seal rings, and thus can ensure the moisture resistance and reduce the charge accumulation in each seal ring.

Specifically, the disclosed semiconductor device includes a semiconductor substrate, an interlayer insulating film formed on the semiconductor substrate, an element region formed on the semiconductor substrate, a first seal ring buried in the interlayer insulating film and surrounding the element region, and a second seal ring buried in the interlayer insulating film and surrounding the element region inside or outside the first seal ring. The first seal ring and the second seal ring are each formed of a layered conductive film including at least one linear interconnect layer and at least one linear via layer, and are insulated from each other or electrically connected to each other only in an uppermost one of conductive layers forming the layered conductive film. The first seal ring is electrically insulated from the semiconductor substrate. The second seal ring is electrically connected to the semiconductor substrate.

The disclosed semiconductor device includes the first seal ring electrically insulated from the semiconductor substrate and the second seal ring electrically connected to the semiconductor substrate. This can provide a seal ring structure capable of releasing the charges accumulated during the manufacture to the semiconductor substrate and ensuring the moisture resistance.

### BRIEF DESCRIPTION OF THE DRAWINGS

FIG. 1 is a cross-sectional view illustrating a semiconductor device of a first embodiment, particularly a seal ring region.

FIG. 2 is a plan view illustrating the seal ring region of the semiconductor device shown in FIG. 1.

FIG. 3 is a cross-sectional view illustrating the seal ring region and an element region of the semiconductor device shown in FIG. 1.

FIG. 4 is a cross-sectional view taken along line IV-IV in FIG. 1 as seen from above.

FIG. 5 is a cross-sectional view illustrating a semiconductor device of a first variation of the first embodiment.

FIG. 6 is a cross-sectional view illustrating a semiconductor device of a second variation of the first embodiment.

FIG. 7 is a cross-sectional view illustrating a semiconductor device of a third variation of the first embodiment.

FIG. 8 is a cross-sectional view illustrating a semiconductor device of a fourth variation of the first embodiment.

FIG. 9 shows a cross-sectional view of a semiconductor device according to a second embodiment.

FIG. 10 is a cross-sectional view illustrating a semiconductor device of a first variation of the second embodiment.

FIG. 11 is a cross-sectional view illustrating a semiconductor device of a second variation of the second embodiment.

FIG. 12 is a cross-sectional view illustrating a semiconductor device of a third variation of the second embodiment.

### DETAILED DESCRIPTION

Embodiments will be described below with reference to the drawings. The following description is merely exemplary and does not limit the present disclosure. Further, the present disclosure can be appropriately modified as appropriate within a range where the disclosure is effective.

### First Embodiment

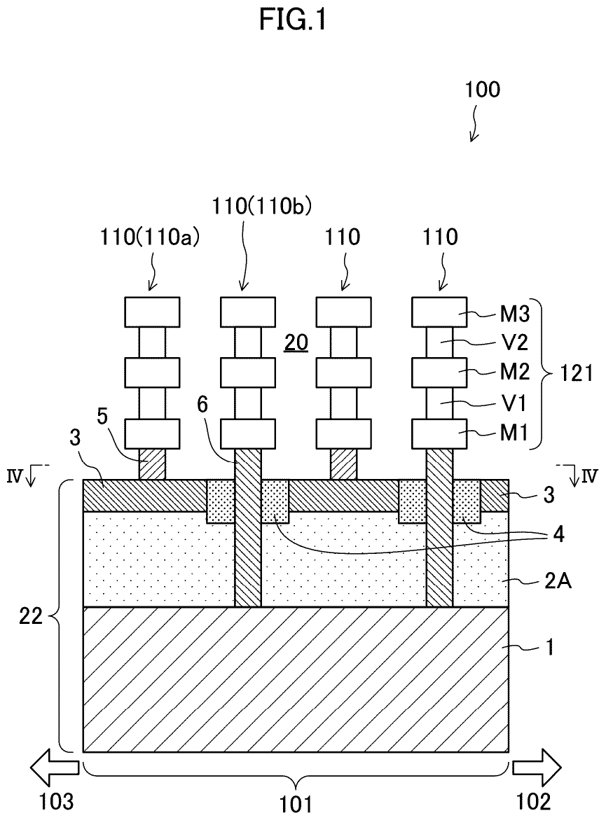

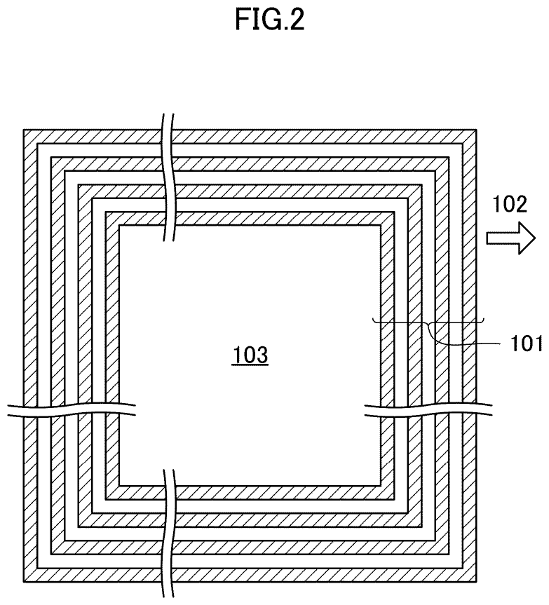

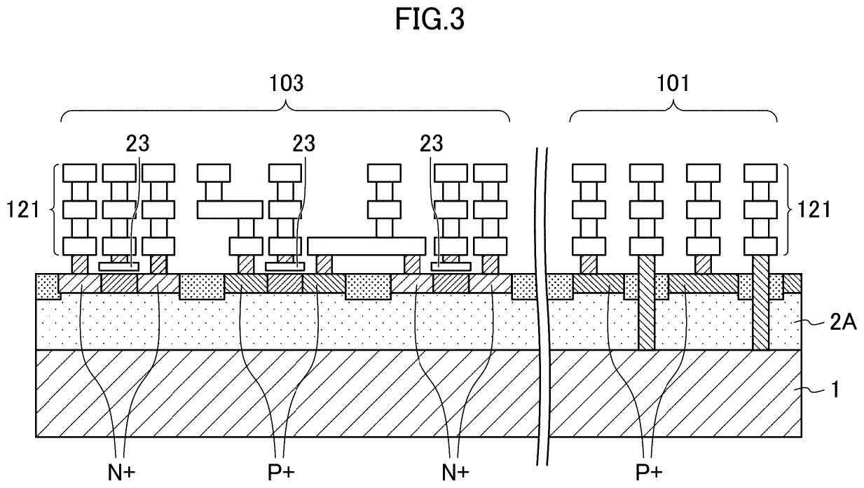

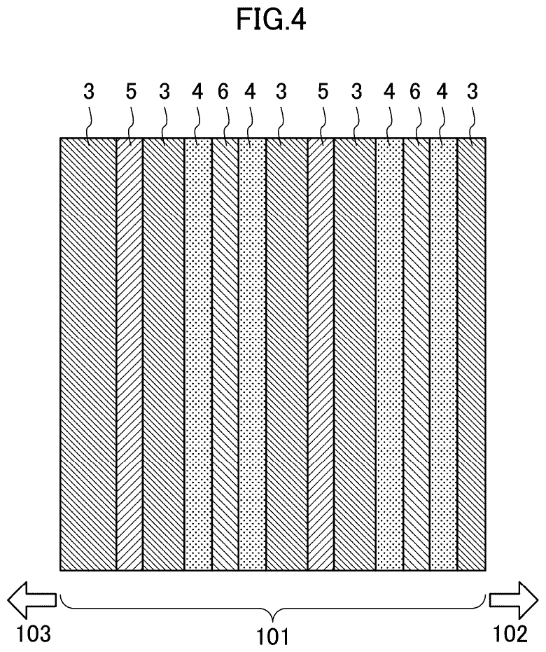

FIGS. 1 to 4 are views illustrating a semiconductor device 100 of the present embodiment. The semiconductor device 100 includes seal rings 110, and FIG. 1 shows a cross section of a seal ring region 101 including the four seal rings 110. FIG. 2 is a plan view schematically illustrating an element region 103 surrounded by the seal ring region 101 including the four seal rings 110. A scribe region 102 is located outside the seal ring region 101. FIG. 3 schematically shows the cross sections of the seal ring region 101 and the element region 103. In the seal ring region 101, the seal rings 110 are formed by a layered conductive film 121. In the element region 103, the layered conductive film 121 forms multiple interconnect layers, and elements such as transistors including gate electrodes 23 are formed. FIG. 4 is a plan view illustrating how first contacts 5, second contacts 6, active layers 3, and second insulating layer 4 are arranged in the seal ring region 101, which will be described in detail later.

The semiconductor device 100 shown in FIG. 1 has a silicon on insulator (SOI) structure. A first insulating layer 2A is formed on the semiconductor substrate 1. The first insulating layer 2A is a buried insulating film and is also referred to as buried oxide (BOX). An active layer 3 is formed on the first insulating layer 2A. A second insulating layer 4 is formed to define the active layer 3. The second insulating layer 4 may have a shallow trench isolation (STI) structure.

An interlayer insulating film 20 is formed above the semiconductor substrate 1, the first insulating layer 2A, and the active layer 3 (they will be hereinafter collectively referred to as a substrate layer 22). The interlayer insulating film 20 includes a stack of layers, but the layers are not shown in detail for easy understanding of the drawing.

The seal rings 110 are formed of the layered conductive film 121 and are buried in the interlayer insulating film 20. In the present embodiment, layers forming the conductive film 121 include an interconnect layer M1, a via layer V1, an interconnect layer M2, a via layer V2, and an interconnect layer M3 that are stacked in this order from the bottom. The interconnect layers M1, M2, and M3 and the via layers V1 and V2 are all formed in a linear shape extending with predetermined widths to surround the element region 103 with no gap.

The element region 103 includes layers of metal interconnect formed of the conductive film 121. The via layers V1 and V2 in the metal interconnect layers mainly serve as plugs connecting the upper and lower interconnect layers to each other at predetermined positions.

These interconnects are called fine interconnects. For high-speed operation of the semiconductor device, a low dielectric constant insulating film called a Low-k film is used as the interlayer insulating film 20 around the interconnects. Use of the Low-k film advantageously reduces the electric capacitance between the interconnects. However, the Low-k film tends to be less resistant to moisture. That is, if moisture enters the element region 103, it causes defects such as a short circuit between the interconnects. To avoid such defects, the seal rings 110 are arranged to surround the element region 103 to block the moisture from entering the element region 103.

The layers of the conductive film 121 constituting the seal rings 110 (and the metal interconnect layers in the element region 103) are sequentially formed by, for example, embedding a conductive material such as Cu in grooves or holes provided in the layers of the interlayer insulating film 20.

In some cases, however, the material cannot be suitably embedded or the embedded material may be lost. If the seal ring 110 has portions (voids) not embedded with Cu, moisture may possibly enter the element region 103 through the portions. In this case, the seal ring 110 is not effective.

Such voids are more likely to occur as the metal interconnects and the seal rings 110 are made smaller due to miniaturization of the device, and are particularly disadvantageous for the fine interconnects. Further, the via layers V1 and V2 constituting the seal ring 110 are linearly elongated (linear vias). In this case, a Cu-containing polymer which is difficult to remove is likely to be generated at the bottom of the linear vias due to a difference in dry etching rate between the linear vias and the vias serving as plugs. As a result, Cu is not appropriately embedded, which may cause the voids. The voids are likely to occur when the seal ring is electrically connected to the semiconductor substrate. These facts have been newly found by the inventors of the present invention.

In the manufacturing process of the semiconductor device, charges may accumulate (charge buildup) in the conductive film 121 being manufactured. The accumulated charges may damage the semiconductor device being manufactured, for example, melt a metal portion or any other part by arcing (abnormal discharge). Thus, it is desirable to release the charges.

Among the seal rings 110 (four seal rings) of the semiconductor device 100, the first seal ring 110a is electrically connected to the active layer 3 via the first contact 5. The second seal ring 110b is electrically connected to the semiconductor substrate 1 via the second contact 6 penetrating the first insulating layer 2A and the second insulating layer 4.

FIG. 4 is a cross-sectional view taken along line IV-IV in FIG. 1 as seen from above. Assuming that the interlayer insulating film 20 is transparent, FIG. 4 shows the cross sections of the first and second contacts 5 and 6, and the active layer 3 and the second insulating layer 4 arranged below the first and second contacts 5 and 6.

As described above, the voids are likely to occur in the conductive film 121 when a current flows through the semiconductor device 100. However, the voids are less likely to occur because the first seal ring 110a is electrically connected to the active layer 3, but is not electrically connected to the semiconductor device 100. Providing the first seal ring 110a keeps the voids from occurring, and thus reliably keeps the moisture from entering the element region 103.

Further, providing the second seal ring 110b electrically connected to the semiconductor substrate 1 can release the charges to the semiconductor substrate 1. This can substantially reduce the charge accumulation in the second seal ring 110b electrically connected to the semiconductor substrate 1, and can also reduce the charge accumulation in the first seal ring 110a insulated from the semiconductor substrate 1. This is because the second seal ring 110b functions as a path for releasing the current and reduces the charges that may accumulate in various other portions, and as a result, reduces the charges that may accumulate in the first seal ring 110a.

So far, all the seal rings are electrically connected to the semiconductor substrate for the reduction of the charge accumulation. However, as the inventors have newly found, electrically connecting all the seal rings 110 to the semiconductor substrate 1 is not an essential countermeasure against the charge accumulation.

Thus, in the semiconductor device 100 of the present embodiment, the voids are less likely to occur particularly in the first seal ring 110a, and the charge accumulation can be reduced not only in the second seal ring 110b, but in the first seal ring 110a as well.

The other seal rings 110 of the semiconductor device 100 may have the same structure as the first seal ring 110a or the second seal ring 110b.

In the example of the present embodiment, the innermost seal ring 110 (the seal ring closest to the element region 103) is referred to as the first seal ring 110a, and the adjacent seal ring 110 is referred to as the second seal ring 110b, but they may be reversed.

If the semiconductor device 100 includes three or more seal rings 110, it is preferable that the first seal rings 110a electrically connected to the active layer 3 and the second seal rings 110b electrically connected to the semiconductor device 100 are alternately arranged. This arrangement allows easy reduction of the charge accumulation in the second seal rings 110b by using the first seal rings 110a as the path for releasing the charges.

Although the four seal rings 110 are provided in the present embodiment, the effect of reducing the charge accumulation is exhibited as long as at least one first seal ring 110a and at least one second seal ring 110b are provided. The number of the second seal rings 110a may be different from the number of the first seal rings 110b. That is, the device may include three seal rings 110 or more than four seal rings 110.

The four seal rings 110 in the semiconductor device 100 of the present embodiment are not electrically connected to each other. Thus, the effect of reducing the voids and the charge accumulation is exhibited independently by each of the seal rings 110.

### First Variation of First Embodiment

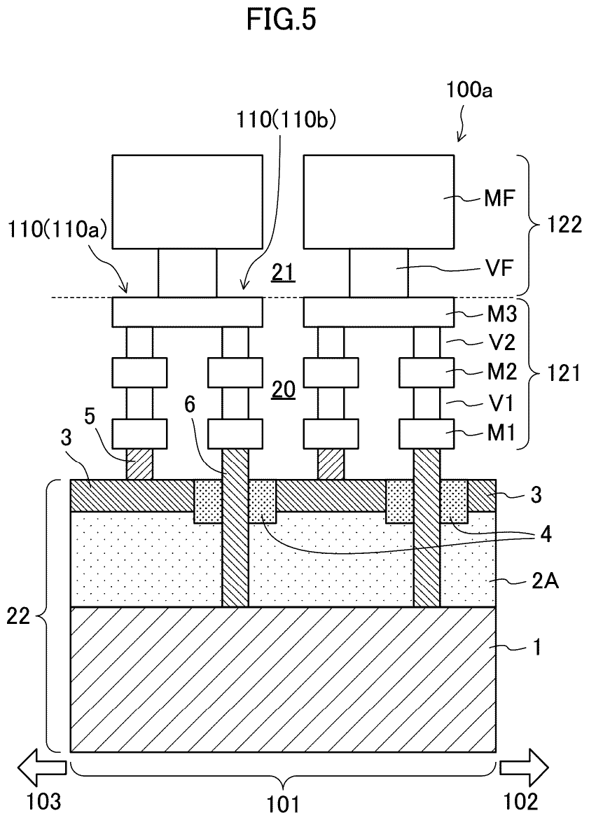

A first variation of the first embodiment will be described below. FIG. 5 shows a schematic cross section of a semiconductor device 100a of the present variation.

The semiconductor device 100a is obtained by forming an upper interlayer insulating film 21 on the interlayer insulating film 20 of the semiconductor element 100 of the first embodiment (FIG. 1) and an upper conductive film 122 buried in the upper interlayer insulating film 21. The upper conductive film 122 has a layered structure including an upper via layer VF and an upper interconnect layer MF and constitutes a second interconnect system on the interconnect system formed of the conductive film 121 (hereinafter may also be referred to as a first interconnect system).

The interconnect layer M3, which is the uppermost layer of the conductive film 121, is widened to connect the via layers V2 of the first seal ring 110a and the second seal ring 110b adjacent to each other. The upper via layer VF is wider than the via layer V1 and is formed in a one-to-one relationship with the interconnect layer M3. The upper interconnect layer MF is wider than the interconnect layers M1 and M2 and as wide as the interconnect layer M3. The upper interconnect layer MF is thicker than the interconnect layers M1 to M3.

The interlayer insulating film 20 is a Low-k film, whereas the upper interlayer insulating film 21 is not the Low-k film but a general interlayer insulating film. The Low-k film generally refers to a film of a material having a relative dielectric constant of three or less, for example, SiOC or SiOCH. A general interlayer insulating film which is not a Low-k film has a relative dielectric constant of four or more, and is made of, for example, SiO₂, SiN, or SiON.

The first interconnect system formed of the conductive film 121 has a strict design rule (designed to have small width and thickness) and includes the interlayer insulating film 20 formed of a Low-k film, and thus forms the voids easily. On the other hand, the interconnect system provided above the interconnect layer M3 and formed of the upper conductive film 122 (hereinafter may also be referred to as a second interconnect system) has a less strict design rule. Further, the upper conductive film 122 is not a Low-k film, and the voids are less likely to occur. Thus, the moisture resistance is less likely to be impaired if the voids are formed.

The charges accumulate also in the upper conductive film 122 during the manufacture of the semiconductor device 100a.

To address the charge accumulation, the interconnect layer M3 is widened to connect the via layers V2 of the first seal ring 110a and the second seal ring 110b adjacent to each other. Thus, potentials separated for each seal ring 110 are connected in the via layers V2 and other layers below. This can release the charges accumulated in the formation of the second interconnect system to the semiconductor device 100.

The voids are formed in the formation of the first interconnect system (the conductive film 121 and other layers). Thus, although the first seal ring 110a with the first contact 5 connected to the active layer 3 is electrically connected to the semiconductor device 100 via the interconnect layer M3 and the second seal ring 110b, no void is formed in the conductive film 121 which has been already formed.

When two or more pairs of the first seal ring 110a and the second seal ring 110b are provided (two pairs are provided in the example of FIG. 5), the first seal rings 110a and the second seal rings 110b are preferably alternately arranged to connect the potentials. However, the seal rings can be arranged in the order of the first seal ring, the second seal ring, the second seal ring, and the first seal ring.

From this viewpoint, the first seal ring 110a and the second seal ring 110b are preferably electrically connected only in the uppermost layer of the conductive film 121.

In this variation, only the first interconnect system (a portion formed of the conductive film 121) is referred to as the seal ring 110 (the first seal ring 110a and the second seal ring 110b). However, in the seal ring region 101, the second interconnect system (a portion formed of the upper conductive film 122) also functions as the seal ring.

In the example of FIG. 5, the first seal ring 110a and the second seal ring 110b are connected by the interconnect layer M3 buried in the low dielectric constant interlayer insulating film 20. However, the first seal ring 110a and the second seal ring 110b may not be electrically connected to each other in the interlayer insulating film 20, and may be electrically connected to each other by the second interconnect system (including the upper via layer VF and the upper interconnect layer MF) in the upper conductive film 122. In this case, the upper via layers VF may be formed independently of each other on the interconnect layer M3 which is the uppermost layer in FIG. 1, and the upper via layers VF may be connected to each other by the wide upper interconnect layer MF.

### Second Variation of First Embodiment

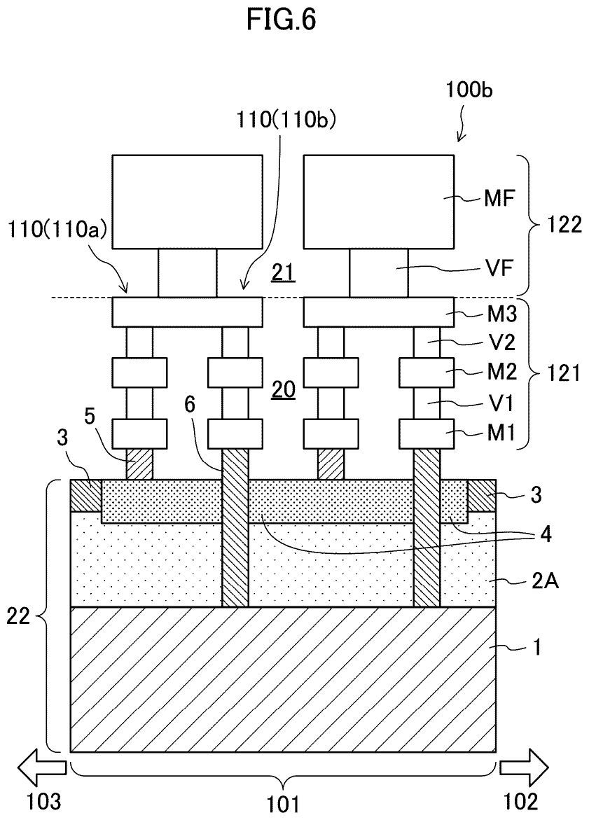

A second variation of the first embodiment will be described below. FIG. 6 shows a schematic cross section of a semiconductor device 100b of this variation.

In the semiconductor device 100a of the first variation (FIG. 5), the first contact 5 is connected to the active layer 3. In contrast, the semiconductor device 100b of this variation (FIG. 6) includes the second insulating layer 4 formed in a wider region, and the first contact 5 is connected to the second insulating layer 4.

In this configuration, the charges are much less likely to come out of the first seal ring 110a than in the first variation, reducing the formation of the voids more reliably.

### Third Variation of First Embodiment

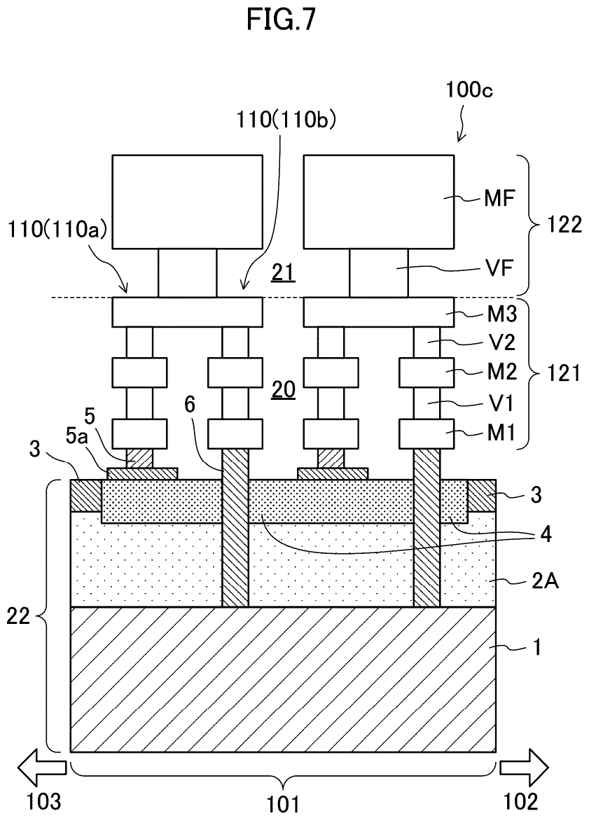

A third variation of the first embodiment will be described below. FIG. 7 shows a schematic cross section of a semiconductor device 100c of this variation.

The semiconductor device 100c of this variation is obtained by forming a polysilicon layer 5a on the second insulating layer 4 of the semiconductor device 100b of the second variation (FIG. 6). The first seal ring 110a is connected to the polysilicon layer 5a via the first contact 5.

In this variation, the first seal ring 110a is insulated from the semiconductor substrate 1 by the second insulating layer 4 and the first insulating layer 2A, reducing the formation of the voids.

The polysilicon layer 5a may be formed not on the second insulating layer 4 but on the active layer 3. Specifically, in the semiconductor device of the first variation shown in FIG. 5, the polysilicon layer 5a may be formed on the active layer 3, and the first contact 5 may be connected to the polysilicon layer 5a.

Also in this case, the first seal ring 110a and the semiconductor substrate 1 are insulated from each other by the first insulating layer 2A, reducing the formation of the voids. If the charges remaining in the polysilicon layer 5a of this variation are fewer than the charges remaining in the active layer 3 of the first embodiment (FIG. 5), the effect of reducing the voids is exhibited more remarkably than in the first embodiment. This can be achieved by, for example, making the polysilicon layer 5a of this variation thinner than the active layer 3 of the first embodiment.

### Fourth Variation of First Embodiment

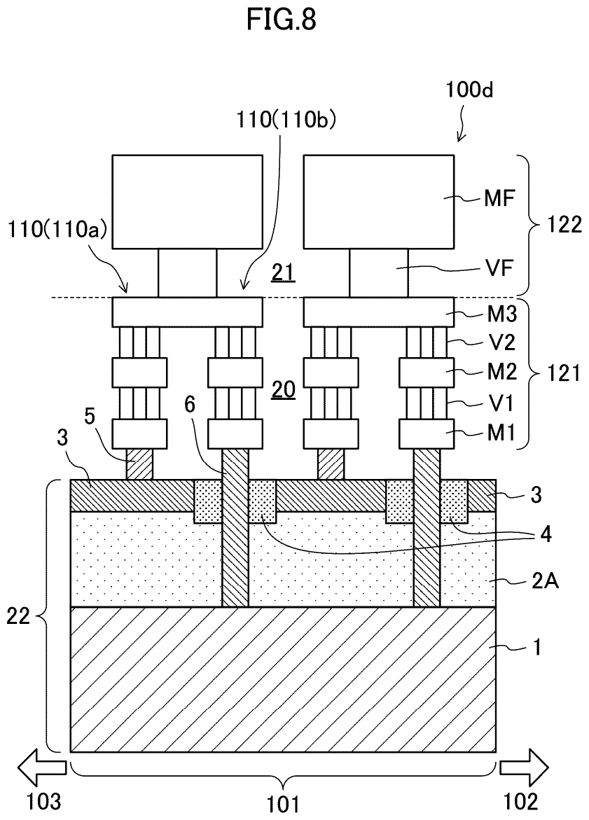

A fourth variation of the first embodiment will be described below. FIG. 8 shows a schematic cross section of a semiconductor device 100d of this variation.

The semiconductor device 100d of this variation is obtained by modifying the semiconductor device 100a of the first variation (FIG. 4) by forming the via layers V1 and V2 each of which is formed of two linear vias. Thus, each of the via layers V1 and V2 surrounds the inner region twice.

Increasing the number of the linear vias in this way can increase the volume of the metal portion of the seal ring 110. This can improve the strength. For example, the seal ring 110 can be made less susceptible to physical damage during blade dicing and thermal damage during laser grooving. Each of the via layers V1 and V2 may be configured to include three or more linear vias.

FIG. 8 is a schematic view showing the semiconductor device in common with the other embodiments and the variations. Thus, the linear vias constituting each of the via layers V1 and V2 are shown narrower than the via layers V1 and V2 each including the single line via shown in FIG. 5 and other drawings. However, the present disclosure is not limited to this configuration. In the semiconductor device 100d of this variation, each of the via layers V1 and V2 may include two or more linear vias as wide as the via layers V1 and V2 shown in FIG. 5 and other drawings. In this case, the interconnect layers M1 and M2 are designed to be sufficiently wide.

If the volume of the metal portion, that is, the total volume of the linear vias, increases although each linear via is narrowed, the seal ring will improve in strength. Further, narrowing the linear vias lowers the etching rate during processing, and time for which Cu is exposed to etching is reduced. This advantageously reduces the formation of the voids.

### Second Embodiment

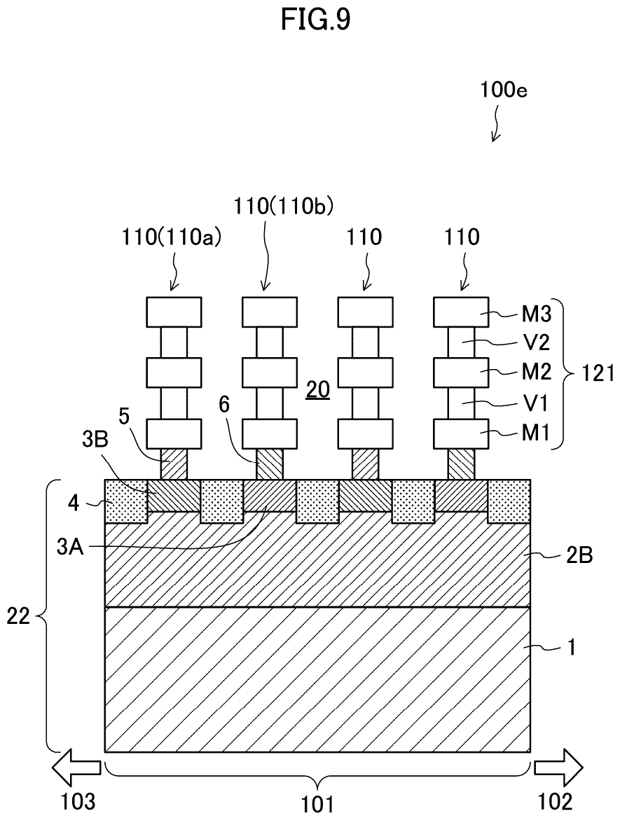

A second embodiment of the present disclosure will be described below. FIG. 9 shows a schematic cross section of a semiconductor device 100e of the present embodiment.

While the device of the first embodiment (FIG. 1) has the SOI structure, the semiconductor device 100e of the present embodiment has a substrate layer 22 including a P-type well 2B formed on a P-type semiconductor substrate 1.

An upper portion of the P-type well 2B is divided into sections by the second insulating layer 4, and P-type impurities and N-type impurities are implanted into the sections to form P-type impurity regions 3A and N-type impurity regions 3B.

The first seal ring 110a is connected to the N-type impurity region 3B via the first contact 5. The N-type impurity region 3B forms a pn junction with the P-type well 2B, and no current flows between the N-type impurity region 3B and the P-type well 2B. This insulates the first seal ring 110a from the semiconductor substrate 1. Thus, the voids are less likely to occur in the first seal ring 110a.

The second seal ring 110b is connected to the P-type impurity region 3A via the second contact 6. The P-type impurity region 3A is electrically connected to the P-type well 2B and the P-type semiconductor substrate 1. Thus, the second seal ring 110b is electrically connected to the semiconductor substrate 1. This can release the charges accumulated in the second seal ring 110b to the semiconductor substrate 1.

This configuration of the present embodiment can also reduce the formation of the voids and can release the accumulated charges to the semiconductor substrate 1.

In the present embodiment (and the following variations), the conductivity types (P-type/N-type) of the respective sections may be reversed.

### First Variation of Second Embodiment

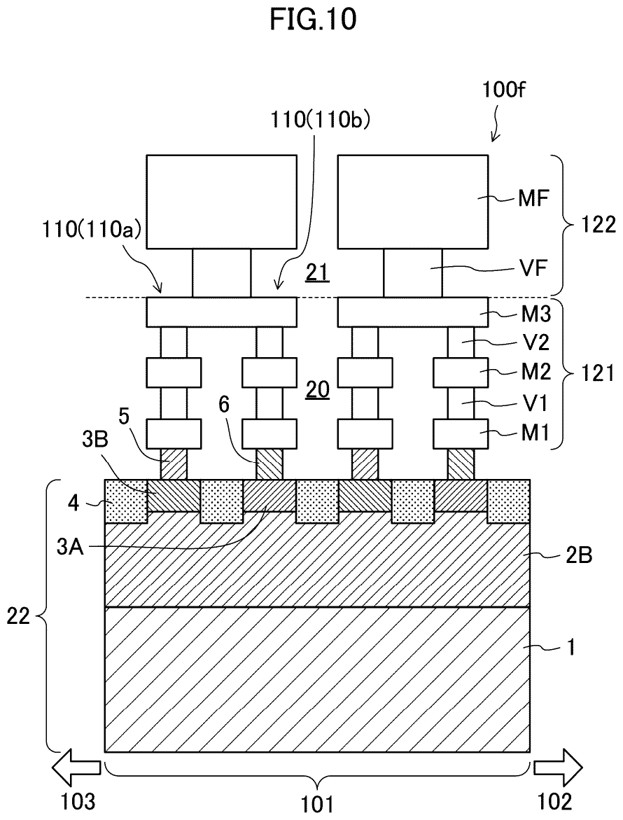

A first variation of the second embodiment will be described below. FIG. 10 shows a schematic cross section of a semiconductor device 100f of this variation.

The semiconductor device 100f of this variation includes an upper interlayer insulating film 21, which is a general insulating film, on the interlayer insulating film 20 made of a Low-k film, in the same manner as the semiconductor device of the first variation (FIG. 5) of the first embodiment. In the upper interlayer insulating film 21, a second interconnect system formed of the upper conductive film 122 and including a via layer VF and an interconnect layer MF is buried. In the first interconnect system in the interlayer insulating film 20, which is a Low-k film, the uppermost interconnect layer M3 is widened to connect the via layer V2 of the first seal ring 110a and the via layer V2 of the second seal ring 110b adjacent to each other.

This configuration provides the same advantages as those of the first variation of the first embodiment.

### Second Variation of Second Embodiment

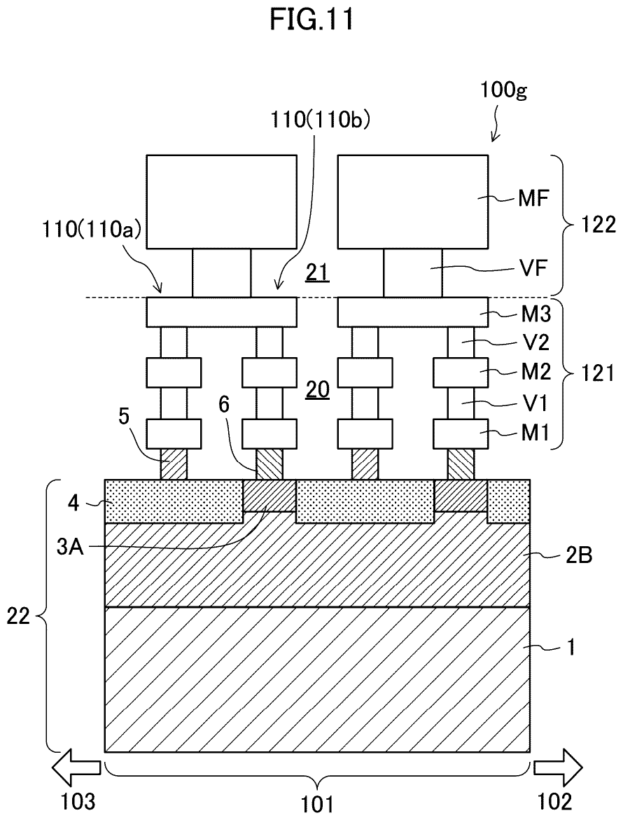

A second variation of the second embodiment will be described below. FIG. 11 shows a schematic cross section of a semiconductor device 100g of this variation.

The semiconductor device 100f of the second variation (FIG. 10) includes the first contact 5 connected to the P-type impurity region 3A. In contrast, the semiconductor device 100g of this variation (FIG. 11) includes the second insulating layer 4 formed in a wider region, and the first contact 5 is connected to the second insulating layer 4.

In this configuration, the charges are much less likely to come out of the first seal ring 110a than in the first variation, reducing the formation of the voids more reliably.

### Third Variation of Second Embodiment

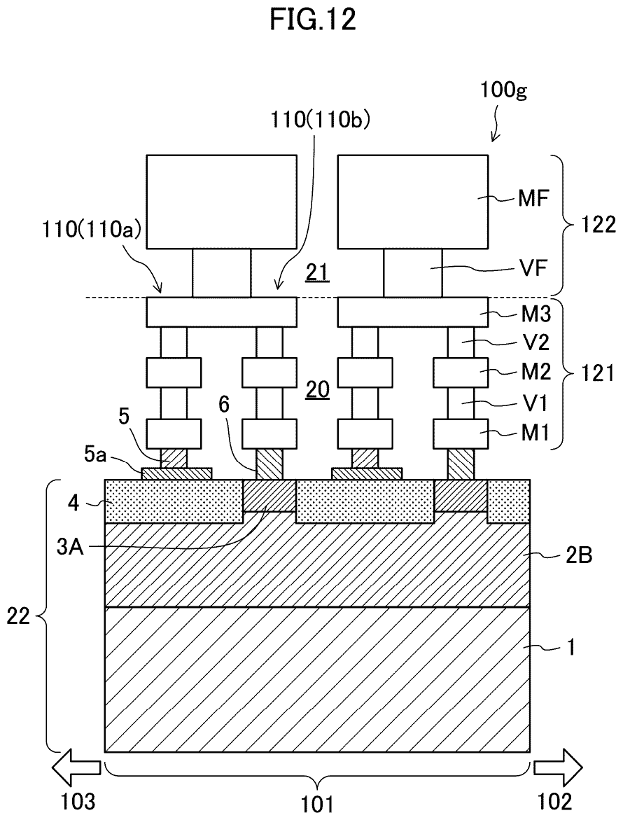

A third variation of the second embodiment will be described below. FIG. 12 shows a schematic cross section of a semiconductor device 100h of this variation.

The semiconductor device 100h of this variation is obtained by forming a polysilicon layer 5a on the second insulating layer 4 of the semiconductor device 100g of the second variation (FIG. 11). The first seal ring 110a is connected to the polysilicon layer 5a via the first contact 5.

In this variation, the first seal ring 110a is insulated from the semiconductor substrate 1 by the second insulating layer 4 and the first insulating layer 2A, reducing the formation of the voids.

The polysilicon layer 5a may be formed not on the second insulating layer 4, but on the N-type impurity region 3B in the semiconductor device of the first variation shown in FIG. 5. The first contact 5 is connected to the polysilicon layer 5a.

In this configuration, the first seal ring 110a and the semiconductor substrate 1 are insulated from each other by the pn junction between the P-type well 2B and the N-type impurity region 3B. This reduces the formation of the voids in the first seal ring 110a.

The embodiments described above can be modified in form and detail without departing from the spirit of the claims. The contents of each embodiment can be combined and replaced as appropriate as long as the functions of the subject of the disclosure are not impaired.

The present disclosure is useful as a semiconductor device having a seal ring structure that can release charges built up in a manufacturing process to a semiconductor substrate and can ensure moisture resistance.

What is claimed is:

1. A semiconductor device, comprising: a semiconductor substrate;
an interlayer insulating film formed on the semiconductor substrate;
an element region formed on the semiconductor substrate; and
a first seal ring and a second seal ring buried in the interlayer insulating film, the first seal ring surrounding the element region, the second seal ring surrounding the element region inside or outside the first seal ring, wherein
the first seal ring and the second seal ring are each formed of a layered conductive film including at least one linear interconnect layer and at least one linear via layer, and are insulated from each other or electrically connected to each other only in an uppermost one of conductive layers forming the layered conductive film,
the first seal ring is electrically insulated from the semiconductor substrate, and
the second seal ring is electrically connected to the semiconductor substrate.

2. The semiconductor device of claim 1, further comprising:
an upper interlayer insulating film formed on the interlayer insulating film, wherein
each of the first seal ring and the second seal ring is provided above the conductive film and includes an upper conductive layer constituted of a stack of layers including at least one upper interconnect layer and at least one upper via layer,
the upper interconnect layer is thicker than the interconnect layer, and
the upper conductive layer is buried in the upper interlayer insulating film.

3. The semiconductor device of claim 2, wherein
the interlayer insulating film is made of a low dielectric constant material, and
the upper interlayer insulating film has a higher dielectric constant than the interlayer insulating film.

4. The semiconductor device of claim 1, further comprising:
a first insulating layer formed on the semiconductor substrate;
an active layer formed on the first insulating layer; and
a second insulating layer that defines the active layer, wherein
the first seal ring is connected to the active layer via a first contact, and
the second seal ring is connected to the semiconductor substrate via a second contact penetrating the first insulating layer and the second insulating layer.

5. The semiconductor device of claim 1, further comprising:
a first insulating layer formed on the semiconductor substrate;
an active layer formed on the first insulating layer; and
a second insulating layer that defines the active layer, wherein
the first seal ring is connected to the second insulating layer via a first contact, and
the second seal ring is connected to the semiconductor substrate via a second contact penetrating the first insulating layer and the second insulating layer.

6. The semiconductor device of claim 1, further comprising:
a first insulating layer formed on the semiconductor substrate;
an active layer formed on the first insulating layer;
a second insulating layer that defines the active layer; and
a polysilicon layer formed on the active layer or the second insulating layer, wherein
the first seal ring is connected to the polysilicon layer via a first contact, and
the second seal ring is connected to the semiconductor substrate via a second contact penetrating the first insulating layer and the second insulating layer.

7. The semiconductor device of claim 1, wherein
the at least one via layer in each of the first seal ring and the second seal ring has a plurality of linear vias.

8. The semiconductor device of claim 1, further comprising:
a first semiconductor region and a second semiconductor region provided on the semiconductor substrate, wherein
the first seal ring is electrically connected to the first semiconductor region,
the second seal ring is electrically connected to the second semiconductor region, and
the first semiconductor region is insulated from the semiconductor substrate.

9. The semiconductor device of claim 8, wherein
the semiconductor substrate is a P-type semiconductor substrate,
the first semiconductor region is of an N-type semiconductor region, and
the second semiconductor region is a P-type semiconductor region.
